(19) United States
(12) Patent Application Publication
(10) Pub. No.: US 2020/0296505 A1
(43) Pub. Date: Sep. 17, 2020

(54) Acousto-optic Driver and Acousto-optic Device

(71) Applicant: Changzhou Jutai Electronic Co., Ltd., Changzhou (CN)

(72) Inventors: Min FANG, Changzhou (CN); Jun LIN, Changzhou (CN); Chengqian PAN, Changzhou (CN); Bin CHEN, Changzhou (CN)

(73) Assignee: Changzhou Jutai Electronic Co., Ltd.

(21) Appl. No.: 16/691,174

(22) Filed: Nov. 21, 2019

(30) Foreign Application Priority Data
Oct. 16, 2018 (CN) 201821672398.3

(51) Int. Cl. H04R 3/00; H03F 3/20; G10L 25/18; H05B 47/19; H05B 47/105; H05B 45/39; A63J 17/00

(52) U.S. Cl. CPC H04R 3/00; H03F 3/20; G10L 25/18; H05B 47/19; H04R 2420/07; H05B 45/39; A63J 17/00; H03F 2200/03; H05B 47/105

(57) ABSTRACT

The Invention discloses an acousto-optic driver which has a controller with a Bluetooth communication module, which the controller outputs a first control instruction controlling a luminous mode of an LED lamp bank, the controller further parses an audio signal received by the bluetooth communication module and then outputs a second control instruction, the controller, when parsing the audio signal, acquires a frequency spectrum of the audio signal, and the first control instruction output by the controller adapts a flashing state of the LED lamp bank to a frequency spectrum of played music; an inverter circuit, electrically connected with the controller, the inverter circuit being switched on or switched off according to the first control instruction output by the controller; and an audio power amplifier, electrically connected with the controller, the audio power amplifier amplifying the second control instruction output by the controller.

### CROSS-REFERENCE TO RELATED APPLICATIONS

This application claims priority to Chinese Patent Application No. 201821672398.3 with a filing date of Oct. 16, 2018. The content of the aforementioned application, including any intervening amendments thereto, are incorporated herein by reference.

### TECHNICAL FIELD

The present utility model relates to an acousto-optic driver and an acousto-optic device.

### BACKGROUND ART

A single-path tape control circuit for a Light-Emitting Diode (LED) lamp string, disclosed in CN203523098U, includes a direct current power supply, an input module selecting a flashing state of a loaded LED lamp, a control module outputting a control signal for enabling the loaded LED lamp to present one to N flashing states and a bridge type driving circuit connected to an output end of the control module. The control module is electrically connected with the direct current power supply and the input module respectively. When the input module does not provide any selection signal for the control module, the control module cyclically outputs one to N flashing control signals. When the input module provides a selection signal for the control module, the control module stores and reads the selection signal provided by the input module and outputs a flashing control signal corresponding to the selection signal. A direct current output by the direct current power supply is converted into an accurately controlled non-sinusoidal alternating current according to the flashing control signal provided by the control module.

Although the foregoing tape control circuit may control the LED lamp string to present different flashing states, the product may make a consumer tired after being used for a long time. Therefore, the present product cannot meet requirements of consumers, and the sales of the product tend to decline year by year. For this reason, it is necessary to improve the foregoing product.

### SUMMARY OF THE INVENTION

The present utility model aims to provide an acousto-optic driver and an acousto-optic device combining sounds and light.

The foregoing technical problem is solved through the following technical solutions.

An acousto-optic driver includes:

a controller with a Bluetooth communication module, wherein the controller outputs a first control instruction controlling a luminous mode of an LED lamp bank, the controller further parses an audio signal received by the Bluetooth communication module and then outputs a second control instruction, the controller, when parsing the audio signal, acquires a frequency spectrum of the audio signal, and the first control instruction output by the controller adapts a flashing state of the LED lamp bank to a frequency spectrum of played music;

an inverter circuit, electrically connected with the controller, the inverter circuit being switched on or switched off according to the first control instruction output by the controller; and

an audio power amplifier, electrically connected with the controller, the audio power amplifier amplifying the second control instruction output by the controller.

An acousto-optic device includes an acousto-optic driver, and further includes:

an LED lamp bank, connected to an output end of an inverter circuit; and

a speaker, connected to an output end of an audio power amplifier.

The present utility model has the advantages that after the inverter circuit and the audio power amplifier are connected to an output end of the controller respectively, when the product is used, a control signal of a user is received through the Bluetooth module, then not only the LED lamp bank may be controlled to present different flashing states, but also music may be played; and moreover, the controller may also change a flashing frequency of LEDs along with a frequency of the music. Therefore, according to the present utility model, the aesthetic fatigue of a consumer may be eliminated, and market requirements may be met.

### BRIEF DESCRIPTION OF THE DRAWINGS

FIG. 1 is a schematic diagram of a first embodiment of an acousto-optic driver;

FIG. 2 is a schematic diagram of a second embodiment of an acousto-optic driver; and

FIG. 3 is a schematic diagram of an acousto-optic device according to the present utility model.

### DETAILED DESCRIPTION OF THE INVENTION

### Embodiment 1

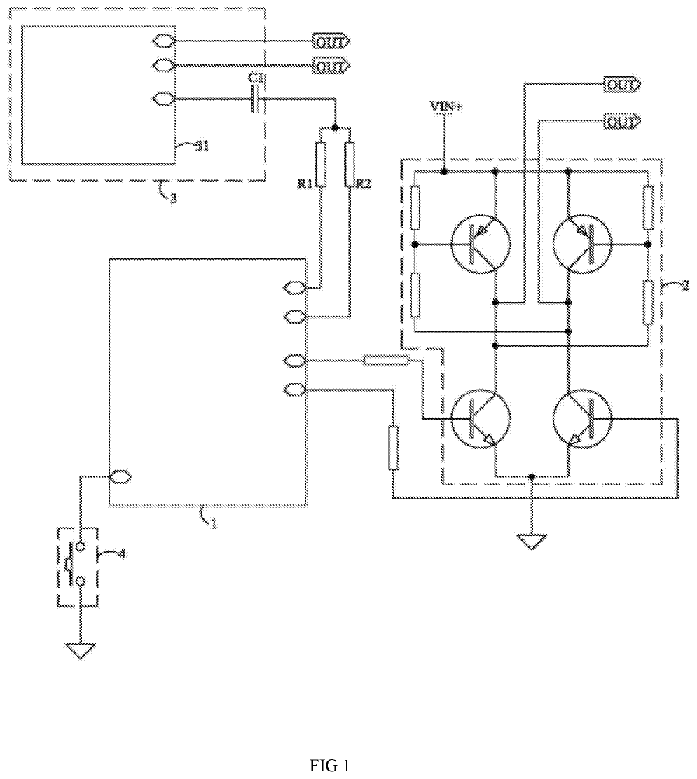

As shown in FIG. 1, an acousto-optic driver of the present embodiment includes a controller 1 with a Bluetooth communication module, an inverter circuit 2 electrically connected with the controller and an audio power amplifier 3 electrically connected with the controller. The controller 1 outputs a first control instruction controlling a luminous mode of an LED lamp bank. The controller 1 further parses an audio signal received by the Bluetooth communication module and then outputs a second control instruction. Each part and a relationship therebetween will be described below in detail respectively.

In the controller 1, the first control instruction sent by the controller 1 is programmed to switch off the LED lamp bank and enable it to present one to N flashing states. An operator switches off the controller 1 for the LED lamp bank or makes it work through a key 4 or mobile equipment connected with the controller 1. The mobile equipment adopts a smart phone. The smart phone is paired with the Bluetooth communication module in the controller 1 through Bluetooth in the phone. Corresponding software may be installed in the smart phone to control the LED lamp bank. Control includes switching-on/off of an LED lamp, brightness regulation, mode setting, password changing, setting of multiple groups of timing and the like.

A music signal played in the smart phone is output through Bluetooth in the smart phone and received through Bluetooth in the controller 1, the controller 1, when parsing the audio signal, acquires a frequency spectrum of the audio signal, and the first control instruction output by the controller 1 adapts the flashing state of the LED lamp bank to a frequency spectrum of the played music. Specifically, the controller 1 converts the audio signal into frequency components of different frequency points of a frequency domain by Fourier transform. Besides Fourier transform, a transform manner may also adopt manners of artificial neural network, support vector machine or the like. After each frequency component is sequenced, a value with a highest amplitude in a sequenced result is extracted as the frequency spectrum. Herein, the frequency spectrum is an amplitude and an frequency of the audio signal. Then, the frequency spectrum is compared with multiple groups of frequency spectrums to be selected. Finally, a group of frequency spectrums the same as or closest to the frequency spectrum are extracted from the multiple groups of frequency spectrums to be selected. A music player in the phone may play music stored in a memory of the phone, and may also play an audio acquired by a pickup of the smart phone (microphone of the phone). Either of the two may be selected from an interface of the music player.

The inverter circuit 2 is switched on or switched off according to the first control instruction output by the controller 1 to control a working state of the LED lamp bank. A structure of the inverter circuit 2 is consistent with a structure of a bridge type driving circuit disclosed in CN203523098U, and will not be elaborated herein.

The audio power amplifier 3 amplifies the second control instruction output by the controller 1. The controller 1 is at least provided with a first audio output end and a second audio output end. A first resistor R1 and a second resistor R2 are further included. One end of the first resistor R1 is connected with the first audio output end, and the other end of the first resistor R1 is connected with an input end of the audio power amplifier 3. One end of the second resistor R2 is connected with the second audio output end, and the other end of the second resistor R2 is connected with the input end of the audio power amplifier 3.

The input end of the audio power amplifier 3 includes a first input end, the other end of the first resistor R1 is connected with the first input end of the audio power amplifier 3, and the other end of the second resistor R2 is connected with the first input end of the audio power amplifier. According to this structure, the other ends of the first resistor R1 and the second resistor R2 are connected in parallel with the first input end of the audio power amplifier 3.

The audio power amplifier 3 includes an audio power amplifier body 31 and a capacitor. One end of the capacitor is electrically connected with the audio power amplifier body, and the other end of the capacitor is the input end of the audio power amplifier. In the present embodiment, the audio power amplifier body 31 is a low-cost single-track power amplifier, and when the other ends of the first resistor R1 and the second resistor R2 are connected in parallel with the first input end of the audio power amplifier 3, the capacitor only includes a first capacitor C1, and the other end of the first capacitor C1 is the first input end, so that the other ends of the first resistor R1 and the second resistor R2 are both connected with the other end of the first capacitor C1.

Since the audio power amplifier body 31 adopts the single-track power amplifier and the other ends of the first resistor R1 and the second resistor R2 are both connected with the other end of the first capacitor C1, when the first audio output end of the controller 1 outputs a high pitch and the second audio output end outputs a low pitch, two tracks are mixed into a track through the first resistor R1 and the second resistor R2 to superpose the high and low pitches. In such a manner, the signal output by the single-track audio power amplifier body 31 may include both the high and low pitches. For example, the first audio output end outputs a 100 MHz signal, the second audio output end outputs a 10 KHz signal, and after integration of circuits where the first resistor R1 and the second resistor R2 are located, the audio signal in the audio power amplifier body 31 at the input end includes both the high pitch and the low pitch.

The circuit of the acousto-optic driver is mounted in a shell of a power plug to form a similar charging plug. During use, an output end of the power plug is connected with the LED lamp bank and a speaker. Therefore, the acousto-optic driver is small in size and convenient to use.

### Embodiment 2

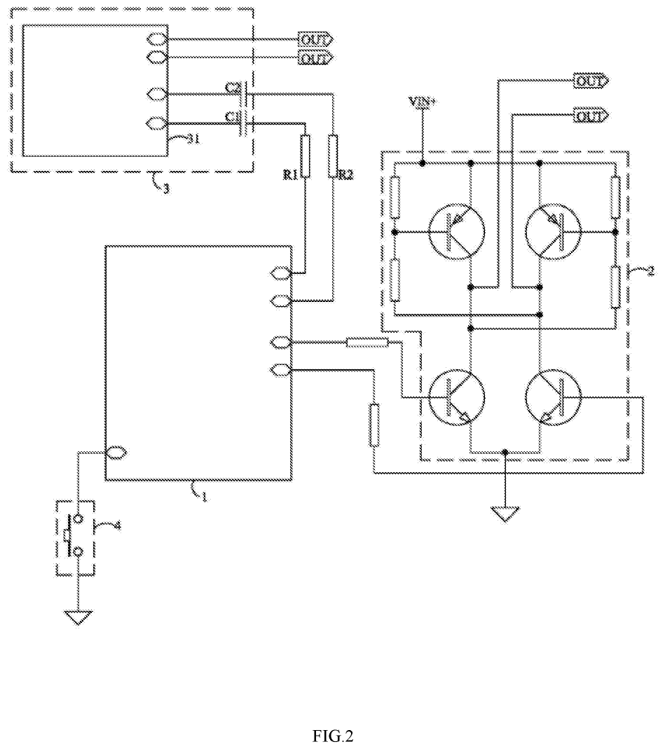

As shown in FIG. 2, the input end of the audio power amplifier includes a first input end and a second input end, one end of the capacitor is electrically connected with the audio power amplifier body, and the other end of the capacitor is the input end of the audio power amplifier. Specifically, the audio power amplifier 3 consists of the audio power amplifier body 31 and the capacitor. The capacitor includes the first capacitor C1 and a second capacitor C2. One end of the first capacitor C1 is connected with the audio power amplifier body 31, and the other end of the first capacitor C1 is the first input end of the audio power amplifier. One end of the second capacitor C2 is connected with the first input end, and the other end of the second capacitor C2 is the second input end of the audio power amplifier.

The other end of the first resistor R1 is connected with the first input end of the audio power amplifier. That is, the other end of the first resistor R1 is connected with the other end of the first capacitor C1. The other end of the second resistor R2 is connected with the second input end of the audio power amplifier. That is, the other end of the second resistor R2 is connected with the other end of the second capacitor C2.

The foregoing contents of the present embodiment are different from those of embodiment 1 and the other structures are the same as those of embodiment 1.

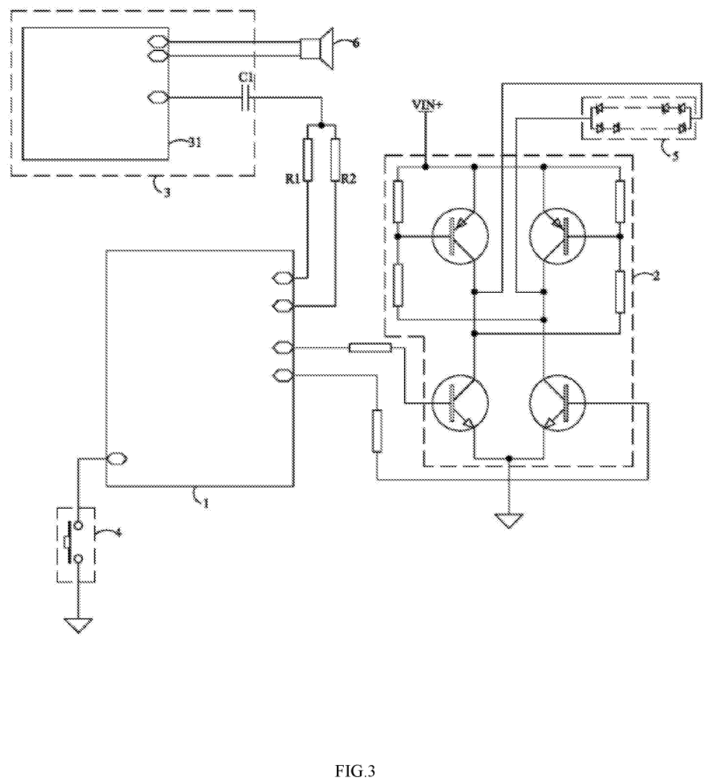

As shown in FIG. 3, an acousto-optic device of the present utility model includes any acousto-optic driver in the foregoing embodiments, and further includes an LED lamp bank 5 connected to an output end of an inverter circuit 2 and a speaker 6 connected to an output end of an audio power amplifier 3. A first control instruction output by a controller 1 enables the inverter circuit 2 to control a working state of the inverter circuit 2 to realize different luminous modes of the LED lamp bank 5, and these luminous modes may refer to descriptions in CN203523098U. A second control instruction output by the controller 1 is amplified through the audio power amplifier 3 to drive the speaker 6 to work, and the speaker 6 may play corresponding music.

We claim:

1. An acousto-optic driver, characterized by comprising:
a controller with a Bluetooth communication module, wherein the controller outputs a first control instruction controlling a luminous mode of a Light-Emitting Diode (LED) lamp bank, the controller further parses an audio signal received by the Bluetooth communication module and then outputs a second control instruction, the controller, when parsing the audio signal, acquires a frequency spectrum of the audio signal, and the first control instruction output by the controller adapts a flashing state of the LED lamp bank to a frequency spectrum of played music;
an inverter circuit electrically connected with the controller, the inverter circuit being switched on or switched off according to the first control instruction output by the controller; and
an audio power amplifier electrically connected with the controller, the audio power amplifier amplifying the second control instruction output by the controller.

2. The acousto-optic driver according to claim 1, wherein the controller is at least provided with a first audio output end and a second audio output end, and
the acousto-optic driver further comprises: a first resistor, one end of the first resistor being connected with the first audio output end and the other end of the first resistor being connected with an input end of the audio power amplifier; and
a second resistor, one end of the second resistor being connected with the second audio output end and the other end of the second resistor being connected with the input end of the audio power amplifier.

3. The acousto-optic driver of claim 2, wherein the input end of the audio power amplifier comprises a first input end, the other end of the first resistor is connected with the first input end of the audio power amplifier, and the other end of the second resistor is connected with the first input end of the audio power amplifier.

4. The acousto-optic driver according to claim 2, wherein the input end of the audio power amplifier comprises the first input end and a second input end, the other end of the first resistor is connected with the first input end of the audio power amplifier, and the other end of the second resistor is connected with the second input end of the audio power amplifier.

5. The acousto-optic driver according to claim 1, wherein the audio power amplifier comprises an audio power amplifier body; and
a capacitor, one end of the capacitor being electrically connected with the audio power amplifier body and the other end of the capacitor being the input end of the audio power amplifier.

6. An acousto-optic device, characterized by comprising the acousto-optic driver according to claim 1 and further comprising:
a Light-Emitting Diode (LED) lamp bank connected to an output end of an inverter circuit; and
a speaker connected to an output end of an audio power amplifier.
